(19) United States
(12) Patent Application Publication
(10) Pub. No.: US 2025/0232802 A1
(43) Pub. Date: Jul. 17, 2025

(54) APPARATUSES, SYSTEMS, AND METHODS FOR NON-TARGETED ON-DIE TERMINATION ADJUSTMENT IN POWER DOWN STATE

(71) Applicant: Micron Technology, Inc., Boise, ID (US)

(72) Inventors: Shunichi Saito, Kanagawa (JP); Yoshinori Matsui, Kanagawa (JP); Osamu Nagashima, Tokyo (JP); Hiroki Takahashi, Tokyo (JP)

(73) Assignee: Micron Technology, Inc., Boise, ID (US)

(21) Appl. No.: 19/011,375

(22) Filed: Jan. 6, 2025

Related U.S. Application Data
(60) Provisional application No. 63/621,404, filed on Jan. 16, 2024.

(51) Int. Cl. G11C 11/4096; G11C 11/4072

(52) U.S. Cl. CPC G11C 11/4096; G11C 11/4072

(57) ABSTRACT

Apparatuses, systems, and methods for powered down non-target on-die termination (NT-ODT adjustment). A memory device has NT-ODT powered down logic which couples a designated pin of the command address terminals to an ODT control circuit, bypassing the command decoder, when the memory device is in a powered down state. An NT-ODT adjustment command received along the designated pin causes the ODT control circuit to change a resistance of the termination circuit of the memory while it is in the powered down state.

### CROSS-REFERENCE TO RELATED APPLICATIONS

This application which claims the filing benefit of U.S. Provisional Application No. 63/621,404, filed Jan. 16, 2024. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During a read operation the physical signal (e.g., the charge) may be coupled to a conductive element to cause a change in voltage. That change in voltage may be amplified and read out to input/output terminals of the device. A write operation may reverse the process, receiving a signal at the terminals and providing a voltage to the memory cell (e.g., to charge the capacitor).

Since voltages may be rapidly applied to the terminals, it may be important to prevent stray voltages from being reflected at the terminals where the memory interfaces with outside devices. The memory may have multiple selectable termination legs which are used to match impedance. It may be important to tune the resistance of the termination resistors.

### BRIEF DESCRIPTION OF THE DRAWINGS

FIG. 1 is a block diagram of a semiconductor device according to an embodiment of the disclosure.

FIG. 2 is a block diagram of a memory system according to some embodiments of the present disclosure.

FIG. 3 is a block diagram of a portion of a memory device according to some embodiments of the present disclosure.

FIG. 4 is a timing chart of an NT-ODT adjustment according to some embodiments of the present disclosure.

FIG. 5 is a timing chart of an NT-ODT adjustment according to some embodiments of the present disclosure.

FIG. 6 is a flow chart of a method of non-target on-die termination adjustment in a powered down state according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory device is stored in a memory array. The information is conveyed as voltages along various internal signal lines. For example, a first voltage may represent a logical high, while a second voltage may represent a logical low. During access operations, such as read and write operations, the signals may be passed to and from the device between data terminals (DQ terminals) of the device and a data bus (DQ bus) which couples the device to a controller. The memory includes input/output (IO) circuits which couple the internal signals to the DQ terminals and DQ bus. The IO circuit includes a termination circuit, which includes one or more selectable resistive legs, each of which include a tunable resistor. The resistive legs may be coupled in parallel, and a number of the resistive legs which are active (e.g., a number of the tunable resistors coupled in parallel) may determine an overall impedance of the termination circuit. This in turn, ensures that the impedance along the line (e.g., the DQ bus) matches the impedance of the terminals (e.g., as set by the termination circuit) to help ensure that there aren't voltage reflections at the DQ terminal. This may be especially important in a memory module, where multiple memory devices may share the same DQ terminals.

During operations, the controller may direct commands to one or more ‘target’ memory devices on the module while ‘non-target’ memories remain idle. A controller of the memory module may send commands to adjust the resistance of the termination circuit of a non-target memory. For example, the controller may send a command to a memory device which includes a first signal which indicates that the termination resistance should be changed along with second signal which indicates a burst length (e.g., how many serial bits are received at each data terminal during a read or write operation). The burst length information may be useful to help manage the timing of the memory device. In some example memory devices, two different burst lengths may be used (e.g., 16 bits and 32 bits). Accordingly, a conventional termination resistance command may require two pins, one for each signal.

In order to save on power, certain non-target memory devices on the module may be placed into a powered down state. When a device is in a powered down state, it draws less power than when it is powered on. While in the powered down state, the devices may generally not respond to any commands (for example along a shared command/address bus of a module), except for a command which causes the powered down device to exit the powered down state. However, it may still be useful to be able to adjust the termination resistance value of non-target memories which are in a power-down state, without the need to turn the memory back on.

The present disclosure is drawn to non-targeted on-die termination in a power down state. A non-target memory device may receive a command to change a termination resistance while it is in a power down state. For example, a single command pin may be designated, and when a signal (e.g., a voltage at an active level) is received along that command pin, the powered down memory device may change the resistance level in the termination circuit without exiting the powered down state. A circuit of the memory device may receive the signal along the command pin and when, the device is in a powered down state, provide that signal as a non-target ODT (NT-ODT) adjustment command. In this manner, a powered down device may enjoy the advantages of being in a powered down state (e.g., reduced power consumption) while still responding to commands which cause it to change the termination resistance.

In some embodiments, the termination circuit may change one step through a cycle of possible resistance values (e.g., low, med, high, low, etc.) responsive to the NT-ODT adjustment command while the device is in the powered down state. In some embodiments, the signal along the designated pin may cause the termination circuit to swap between pre-selected values (e.g., a value when a read operation is performed on the target memory and a value for when a write operation is performed on the target memory). The designated pin may use serial pulses of the signal to determine a burst length for timing purposes rather than using two pins. For example, a single pulse may indicate a change in a module using a first burst length (e.g., 16) and two pulses may indicate a change in a module using a second burst length (e.g., 32).

In an example embodiment, the memory device includes a multiplexer which couples the designated command pin to the command decoder when the device is powered on and couples the designated command pin to the termination circuit when the device is powered down. In this way the designated pin may be used as part of a normal command/address bus when the device is powered on and be used for NT-ODT adjustment when the device is powered down.

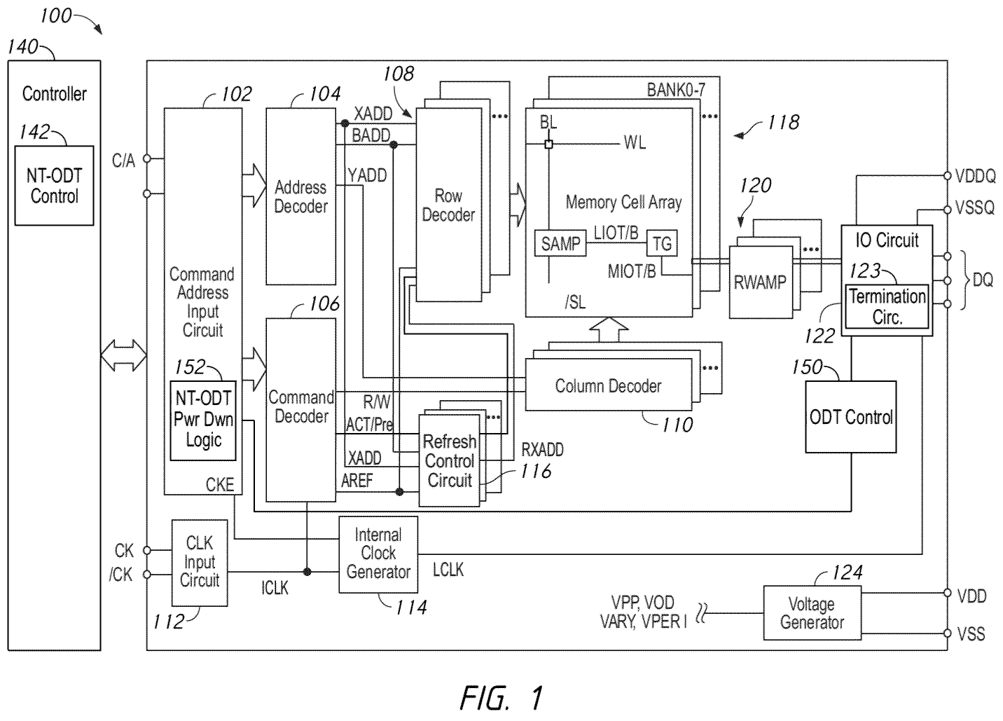

FIG. 1 is a block diagram of a semiconductor device according to an embodiment of the disclosure. The semiconductor device 100 may be a semiconductor memory device, such as a DRAM device integrated on a single semiconductor chip.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. For example, memories may include 4, 16, 32, more or fewer banks. Each memory bank includes a plurality of word lines WL, a plurality of bit lines BL and/BL, and a plurality of memory cells MC arranged at intersections of the plurality of word lines WL and the plurality of bit lines BL and/BL. The selection of the word line WL is performed by a row decoder 108 and the selection of the bit lines BL and/BL is performed by a column decoder 110. In the embodiment of FIG. 1, the row decoder 108 includes a respective row decoder for each memory bank and the column decoder 110 includes a respective column decoder for each memory bank. The bit lines BL and/BL are coupled to a respective sense amplifier (SAMP). Read data from the bit line BL or/BL is amplified by the sense amplifier SAMP and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL or/BL.

The semiconductor device 100 may employ a plurality of external terminals that include command and address (C/A) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ. The external terminals may be coupled to a controller 140 which may operate the memory by providing various signals to the external terminals.

The controller 140 provides the clock terminals with external clocks CK and/CK that are provided to an input circuit 112. The external clocks may be complementary. The input circuit 112 generates an internal clock ICLK based on the clocks CK and/CK. The clock ICLK is provided to the command decoder 106 and to an internal clock generator 114. The internal clock generator 114 provides various internal clocks LCLK based on the clock ICLK. The clocks LCLK may be used for timing operation of various internal circuits. The internal data clocks LCLK are provided to the input/output circuit 122 to time operation of circuits included in the input/output circuit 122, for example, to data receivers to time the receipt of write data.

The controller 140 provides the C/A terminals with commands and memory addresses. There may be a command/address bus which couples the controller 140 to the C/A terminals of the memory device 100. For example, there may be a set of C/A terminals or pins, each coupled to a conductive element of the C/A bus.

The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD.

The controller 140 may provide the C/A terminals with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed. The controller may send commands which place the device 100 into a powered down state, and commands which wake the device 100 and place it into a powered on state. As described in more detail herein, the controller 140 may also transfer an NT-ODT adjustment command, while the memory 100 is powered up or powered down. In some embodiments, while in a powered down state, the device 100 may only responds to NT-ODT adjustment commands and a command to power on the device.

When the device is powered on, the control commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line. The command decoder 106 also provides activation and pre-charge signals to the different banks of the memory. An activation signal ACT may indicate that a word line in that bank should be activated, while a pre-charge signal Pre may indicate that the word lines should be pre-charged (e.g., closed) in anticipation of a next activation command. In some embodiments, the ACT and Pre signals may share a signal line.

The device 100 may receive commands and addresses from the controller 140 as part of an access operation such as a read operation. As part of the access operation, a row address and bank address is received along with an activate command. As part of the access operation, a column address and bank address are received along with a read command. Responsive to the read operation, read data is read from memory cells in the memory array 118 corresponding to the row address and column address. The commands associated with the read operation are received by the command decoder 106, which provides internal commands so that read data from the memory array 118 is provided to the read/write amplifiers 120. Responsive to the activate command the row decoder 108 activates a word line associated with the row address. While the row is active, memory cells along that row are coupled to sense amplifiers activated by the column decoder 110 responsive to the read command to read data out along the LIOT/B lines. The read data is output to outside from the data terminals DQ via the input/output circuit 122. The command decoder 106 may then provide a pre-charge command which may ‘close’ the active row.

The device 100 may receive commands and addresses from the controller 140 as part of an access operation such as a write operation. As part of the write operation, a row address and bank address are received along with an activated command and a column address and bank address are received along with write data and a write command. Responsive to the write operation, write data supplied to the data terminals DQ is written to a memory cells in the memory array 118 corresponding to the row address and column address. The commands associated with the write operation are received by the command decoder 106, which provides internal commands so that the write data is received by data receivers in the input/output circuit 122. Responsive to the activate command the row decoder 108 activates a word line associated with the row address. While the row is active, memory cells along that row are coupled to sense amplifiers activated by the column decoder 110 responsive to the write command to receive write data. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC. The command decoder 106 may then provide a pre-charge command which may ‘close’ the active row.

The device 100 may also perform refresh operations. The refresh operations may be performed as part of an auto-refresh operation, where a controller 140 issues an auto-refresh command or as part of a self-refresh operation, where the memory refreshes itself based on internal commands. The refresh control circuit 116 supplies a refresh row address RXADD to the row decoder 108, which may refresh one or more wordlines WL indicated by the refresh row address RXADD. In some embodiments, the refresh address RXADD may represent a single wordline. In some embodiments, the refresh address RXADD may represent multiple wordlines, which may be refreshed sequentially or simultaneously by the row decoder 108. In some embodiments, the number of wordlines represented by the refresh address RXADD may vary from one refresh address to another. The refresh control circuit 116 may be controlled to change details of the refreshing address RXADD (e.g., how the refresh address is calculated, the timing of the refresh addresses, the number of wordlines represented by the address), or may operate based on internal logic.

The IO circuit 122 includes a termination circuit 123. The termination circuit 123 provides a calibrated impedance value to the DQ terminals, for example to match the impedance of the DQ terminals to the line impedance of the DQ bus between the DQ terminals and the controller 140. The termination circuit 123 includes a number of tunable resistors, which may be selectively coupled to the DQ terminals to provide a chosen impedance. The chosen impedance may be a setting based on properties of the controller and/or DQ bus. For example, the termination circuit 123 includes a number of selectable resistive legs, each with a tunable resistor of NΩ. If X of the tunable legs are active, then the overall value may be (N/X)Ω. For example, if 240Ω resistors are used, then overall values such as 60Ω (four active legs), 40Ω (six active legs), and 30Ω (seven active legs) may be selected. Other values of the resistor and other numbers of legs may be used in other example embodiments.

Each of the tunable resistors may be adjustable in order to ensure that the impedance can be matched to a nominal value (for example, to ensure that each tunable resistor matches a value of 240Ω). The memory may have access to a reference resistor ZQ (not shown in FIG. 1) which has the nominal value. The reference resistor ZQ may be a resistor manufactured with extremely narrow tolerances (e.g., 5%, 1%, or 0.1% etc.) As part of the calibration operation, the resistance of each of the tunable resistors of the termination circuit 123 is adjusted to match the resistance of the reference resistor ZQ.

There may be circumstances where the controller 140 changes the impedance provided by the termination circuit 123. The controller 140 includes an NT-ODT control circuit 142, which may determine when to change the termination impedance of the memory 100. For example, the termination circuit 123 may generally be set to a value used when the controller is performing a read command on some other memory device on the module. If the controller 140 is performing a write operation on the other memory device, then the NT-ODT control circuit 142 may send a command to the memory 100 to have the termination impedance changed to a level appropriate for write operations for a time.

For example, when the device 100 is powered on, the NT-ODT control circuit 142 may send a two bit command to two C/A pins. The first signal (e.g., the first bit) of the command may indicate that a change to the termination impedance should occur and the second signal (e.g., the second bit) of the command may indicate how long the change should be in effect (e.g., based on a burst length). When powered on, the commands may be passed to the command decoder 106, which may generate internal signals which instruct an ODT control circuit 150 to adjust the termination impedance. For example, the ODT control circuit 150 may change an active number of legs of the variable resistor in the termination circuit 123.

When the device 100 is powered down, the command decoder may generally be inactive. However, the NT-ODT control circuit 142 of the controller 140 may still send NT-ODT adjustment commands and the device 100 may still respond to them, without exiting the powered down state. When the device 100 is in a powered down mode, an NT-ODT power down logic circuit 152 may bypass the command decoder 106 and couple a C/A pin to the ODT control circuit 150. When the memory 100 is in the powered down mode, the NT-ODT control circuit 142 provides NT-ODT adjustment commands along the single designated C/A pin which bypasses the command decoder. The single C/A pin may be used for both sending the first and the second signals. For example, a single pulse along the designated pin may cause the ODT control circuit 150 to change the termination impedance for a first amount of time (e.g., a 16 bit burst length), while two pulses along the designated pin may cause the ODT control circuit 150 to change the termination impedance for a second amount of time (e.g., a 32 bit burst length).

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The internal potential VPP is mainly used in the row decoder 108, the internal potentials VOD and VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

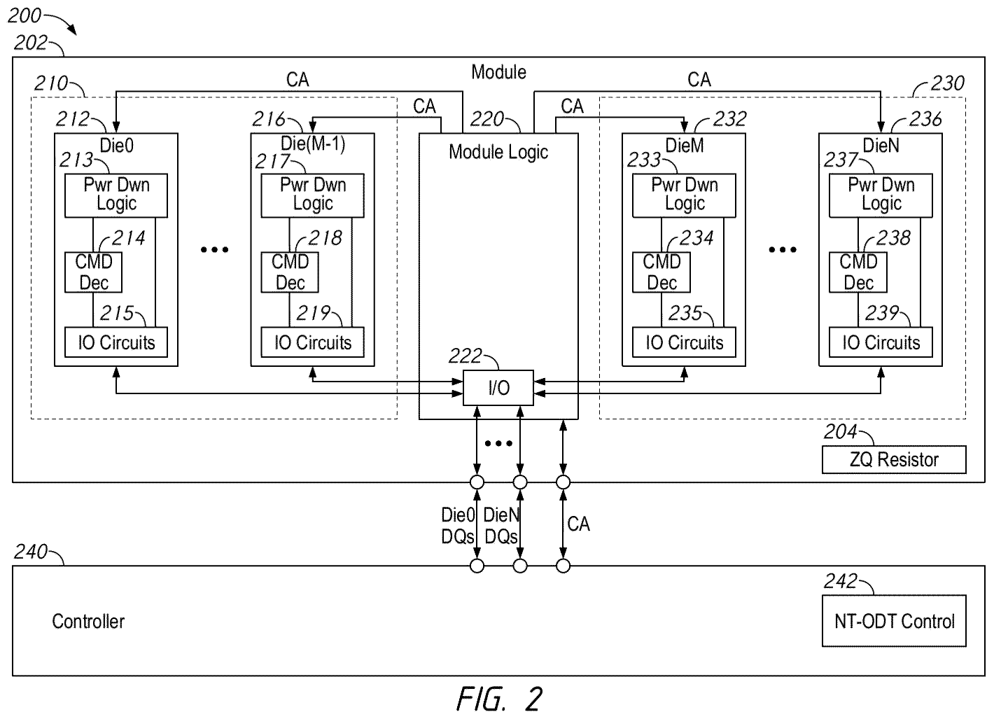

FIG. 2 is a block diagram of a memory system according to some embodiments of the present disclosure. The example of FIG. 2 shows an embodiment where multiple memories are packaged together into a memory module 202. The termination circuitry may especially be important in such an embodiment, as certain memory dies may share external DQ terminals. Accordingly, when one (target) memory device coupled to the shared terminal is accessed, reflections at the terminal may cause signals to be improperly sent to the other, non-target, memory coupled to that terminal. However, it should be appreciated that the embodiments of the present disclosure may work both in stand-alone memories and in memories packaged together into modules.

The memory system 200 includes a module 202 and a controller 240. The memory module 202 includes a number of memory dice 212, 216, 232, and 236. In some embodiments, each of the memory dice 212, 216, 232, and 236 may be implemented by the memory device 100 of FIG. 1. The memory module 202 includes module logic 220 which manages access to the memory dice on the module 202. For example, the module logic 220 may include an input/output circuit 222 which may act as a buffer to provide signals between the terminals of the memory dice and the external terminals of the module 202. The external terminals of the module 202 interface with the controller 240. The module 202 also includes a reference resistor 204, which is used in calibration operations.

The memory module includes a number of memory dies, organized into channels. Memory dies 212 and 216 are shown as part of a first channel 210, and memory dies 232 and 236 are shown as part of a second channel 230. Each channel may have a number of memory dies. For example, each channel may have 5 memory dies. More or fewer dies per channel may be used in other example embodiments. Similarly, the module 202 may have more or fewer channels. For example, FIG. 2 shows two channels 210 and 230, one on either side of module logic 220. There may be additional channels (and additional memory dies) located on the back of the physical module chip, for a total of 4 channels. More or fewer than 4 channels may be used in other example embodiments. Some channels may share external DQ terminal of the module with each other and may be referred to as ‘ranks’.

Since the memory dies may generally be similar, only the operation of a single example memory die will be discussed with respect to the operation of the module 202. The module 202 is coupled to the controller 240 along a set of terminals. Example command/address (CA) terminals, along with sets of the data input/output (DQ) terminals are shown, however additional terminals and connections may exist in other example embodiments. During an example read operation, the controller 240 provides the read command along with die identification information, which specifies the channel (and/or the individual die) to be accessed along with the row address, column address, and bank address to be accessed within the memory. The module logic 220 routes the C/A signals to the memory dies, and the specified die, in this example Die0 212, responds. The specified Die reads data from the specified row, bank, and column, and provides that data via IO circuit 215 (e.g., 122 of FIG. 1) along internal signal lines to the module IO circuit 222, which routes the data to external data terminals.

Each die on the module 202 is associated with a set of external DQ terminals. The external DQ terminals may be shared by multiple dies. For example, the memory Die0 212 has 16 DQ terminals, each of which corresponds to one of 16 external Die0 DQ terminals on the module. Those 16 external Die0 DQ terminals may also be used by another die (e.g., located on the backside of the module 202) which is part of a different channel. When external DQ terminals are shared, one of the dies which shares the DQ terminal may be a target die of a given operation, while the other die are non-targeted. Other arrangements of DQ terminal sharing may be used in other example embodiments.

During operations, the controller may target one or more of the memory die (for example by sending commands and sending/receiving data to the target die) while the other die may be non-targeted. Some of the non-target die may be in a powered on or powered up state, while other die may be in a powered down state. The powered down die may operate in a low power mode where certain components (e.g., the command decoders, the row and column decoders) receive no (or minimal power) and do not perform regular operations until the device is placed back into a powered up state. While in a powered down state, a memory device (212, 216, 232, and/or 236) may generally only respond to a power on command or to NT-ODT adjustment commands.

The controller 240 may send NT-ODT adjustment commands to change a termination resistance (e.g., how many resistor legs are active) in the IO circuit of a non-targeted memory device. For the sake of explanation, an access operation will be discussed where DieM 232 is the target die and Die0 212 is the non-target die. An NT-ODT control circuit (e.g., 150 of FIG. 1) of the controller 240 may send an NT-ODT adjustment command via the CA bus to the non-target memory die 212. For example the NT-ODT command may be sent along with information which identifies Die0 as the non-target die to be adjusted. Responsive to the NT-ODT adjustment command, the non-target memory die 212 may change a resistance in a termination circuit (e.g., 123 of FIG. 1) of the IO circuit 215. For example, a number of the tunable resistors coupled to the DQ terminals may be changed.

The controller 240 may monitor if the non-target die 212 is powered on or powered off. If the non-target die 212 is powered on, a first type of NT-ODT adjustment command may be sent. If the non-target die 212 is powered down, a second type of NT-ODT adjustment command may be sent. The first type of NT-ODT adjustment command may be sent along a first number of CA terminals, while the second type of NT-ODT adjustment command may be sent along a second number of CA terminals which is less than the first number. For example, when the non-target device is powered on, the NT-ODT adjustment command may be sent along two lines of the CA bus (e.g., two signals in parallel) and when the non-target device is powered down, the NT-ODT adjustment command may be sent along a single line of the CA bus. When the device is powered down, a specific designated CA pin or pins may be used.

Each memory die, such as the non-target die 212, includes a power down logic circuit (e.g., 152 of FIG. 1) which routes the NT-ODT adjustment commands based on the power state of the device. If the device is powered on, then the power down logic circuit 213 may route all of the signals along the CA pins to a command decoder 214, which may generate one or more internal signals to cause adjustments to the termination resistance/impedance. If the device is powered down, then the power down logic circuit 213 may route the signals from one or more designated CA pins to bypass the command decoder and go directly to an ODT control circuit (e.g., 150 of FIG. 1), shown in FIG. 2 as part of the IO circuits 215.

In an example application, the controller 240 may send a NT-ODT adjustment command as part of performing a write operation on a target die 232. For example, the termination impedance value in the IO circuits 215 may generally be set to a value based on performing read operations on the target memory die. However, a different impedance may be used for write operations on the target die. Accordingly, when a write operation is performed on the target die 232, an NT-ODT adjustment command may be sent to the non-target die 212, which indicates that an adjustment should be performed, and also indicates how long that adjustment should be made for (e.g., by indicating the burst length of the write command).

The controller 240 provides a write command along the CA bus along with information which identifies the target die 232. The controller 240 begins transmitting data along the DQ terminals associated with the target die. The NT-ODT control circuit 242 of the controller 240 also sends a NT-ODT adjustment command along the CA bus with information identifying the non-target die 212. If the die 212 is powered on, the NT-ODT control circuit provides two signals along multiple lines of the CA bus, one which identifies that an ODT adjustment should be performed, and one which indicates the burst length. In this example application, two binary signals may be used, one which identifies that the termination impedance should be changed from a pre-set read value to a pre-set write value, and one which indicates whether a burst length of 16 or 32 is being used.

If the die 212 is powered down, the NT-ODT control circuit 242 may send a single signal along fewer CA pins. In this example, the NT-ODT control circuit 242 may use a single CA pin which carries a binary signal which indicates a change in the termination impedance (e.g., from a read value to the write value) for a set period of time. The period of time may correspond to a burst length of 16, and if a burst length of 32 is used, the NT-ODT circuit 242 may send the signal twice so that the change is maintained for twice as long (e.g., a burst length of 32).

In a subsequent operation, the memory 212 may become a target die if the controller 240 performs an access operation, such as a write operation, on it. When the memory 212 is the target die, the controller 240 may issue NT-ODT adjustment commands to one or more non-target memory devices, such as the device 232. The device 232 may be powered down and may operate in a manner analogous to that which was described for when the device 212 was the non-target device.

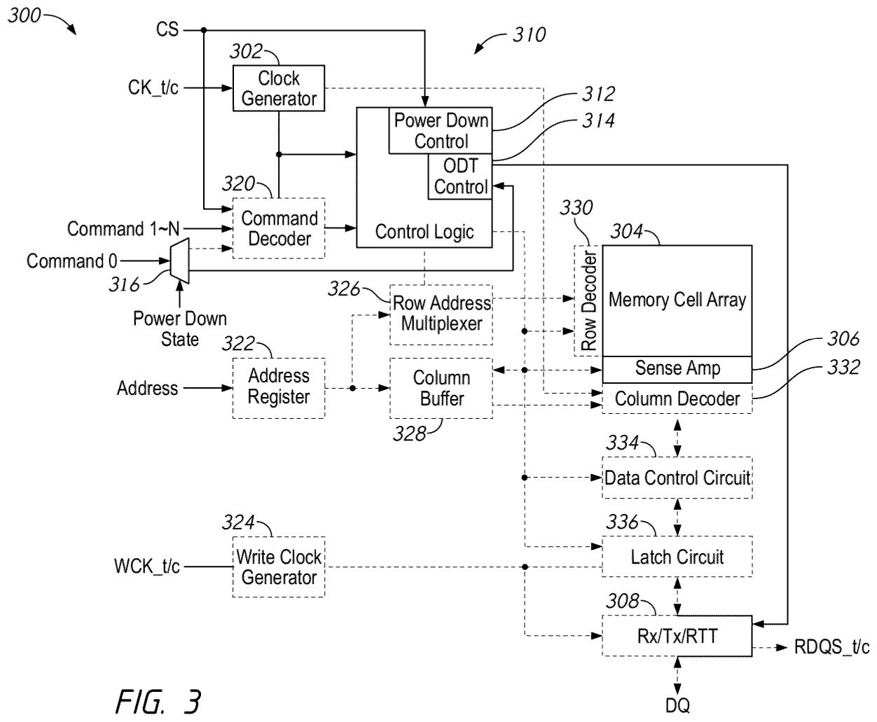

FIG. 3 is a block diagram of a portion of a memory device according to some embodiments of the present disclosure. The memory device 300 may, in some embodiments, implement a portion of the memory device 100 of FIG. 1 and/or any of 212, 216, 232 and/or 236 of FIG. 2. The memory device 300 shows a memory device which is in a powered down state, with components which are non-active in the powered down state represented by a dotted line box and components which remain active in the powered down state represented by a solid line box. Similarly, dotted lines represent signaling pathways which are inactive in the powered down state while solid lines are active signal pathways. For the sake of brevity, some components, signals and operations which were described in detail with respect to FIGS. 1-2 will not be described again with respect to FIG. 3.

The memory device 300 includes a memory array 304 (e.g., 118 of FIG. 1), along with sense amplifiers 306 and associated row and column decoders 330 and 332 (e.g., 108 and 110 of FIG. 1). The memory 300 also includes a command decoder 320 (e.g., 106 of FIG. 1) as well as an address register 322, row address multiplexer 326 and column buffer 328, which may be components of the address decoder (e.g., 104 of FIG. 1). A data control circuit 334, latch circuit 336 and IO circuit 308 may be components of the IO circuit 122 of FIG. 1. The memory 300 also includes a clock circuit 302 (e.g., 114 of FIG. 1) and a control logic circuit 310. The control logic 310 includes a power down control circuit 312 and an ODT control circuit 314. The memory 300 also includes a multiplexer 306, which may implement the NT-ODT power down logic 152 of FIGS. 1 and/or 213, 217, 233, and/or 237 of FIG. 2. During the power down mode, the components 302-314 may generally be active while the components 320-336 may be inactive.

The command bus carries N+1 signals, designated Command 0 to Command N, each of which is received at a corresponding pin of the memory device. The command decoder 320 receives signals from all but one pin, for example Command 1 to Command N. A designated pin, here the first pin Command 0, is provided to the multiplexer 306 instead. The multiplexer receives the signal Command 0 and routes it either to the command decoder 320 or directly to the ODT control circuit 314 based on a power down state. The power down state may be indicated by a power down state signal, which may be provided by the power down control circuit 312. When the power down state indicates the device is powered on, the signal Command 0 is provided to the command decoder 320 with the rest of the command signals. When the power down state indicates the device is powered down, the signal Command 0 is provided to the ODT control circuit 314.

The clock generator 302 receives an external clock signal CK_t/c (e.g., CK and/CK of FIG. 1) and provides one or more internal clocks to the control logic 310. A chip select signal CS is also provided to the control logic 310. The CS signal may indicate that the memory device 300 has been selected by the controller to receive a command. For example, even if the device is the non-targeted device, the CS signal may be still be used to indicate that an NT-ODT adjustment command is intended for the device 300. The ODT control circuit 314 may use the clock signal CK_t/c to manage the timing of various operations.

Responsive to the signal Command 0 from the multiplexer 306, the ODT control circuit 314 may send signals to the IO circuit 308. The IO circuit 308 may include a number of components, such as receivers (Rx), transmitters (Tx) and termination resistors RTT. During the power down mode, the termination resistors may be active while the receivers and transmitters are inactive. The ODT control circuit 314 provides a signal which causes a number of the termination resistors to change for a set period of time. The period of time may be based on a number of cycles of the clock signal CK_t/c or one or more clock signals derived therefrom. For example, for each signal along Command 0, the ODT control circuit 314 may change the termination resistance value for an amount of time which corresponds to a burst length of 16.

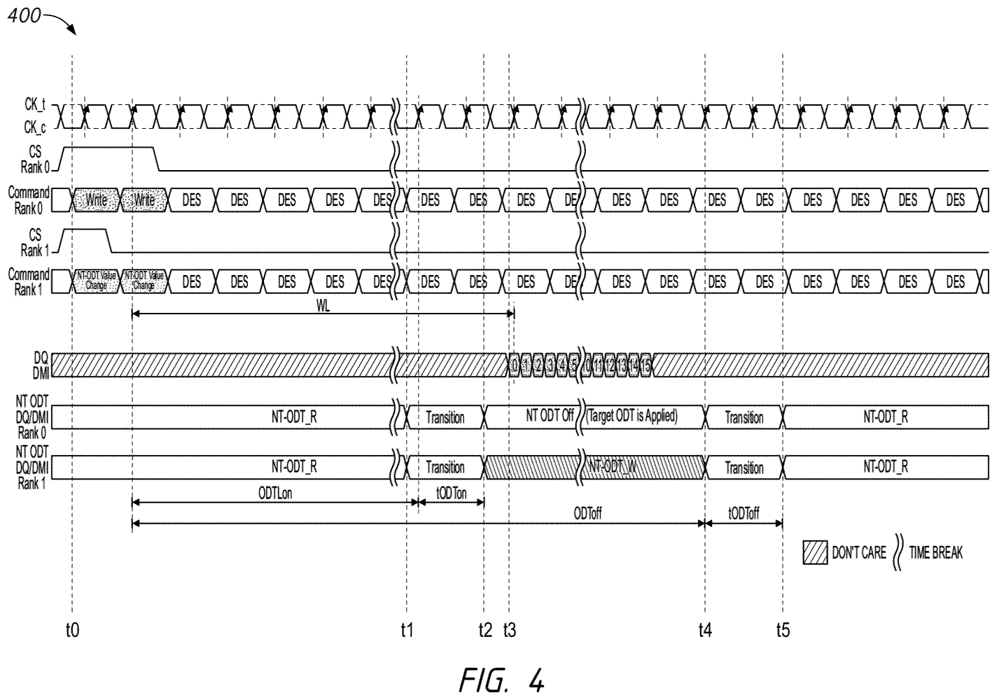

FIG. 4 is a timing chart of an NT-ODT adjustment according to some embodiments of the present disclosure. The timing chart 400 may, in some embodiments, represent the operation of one or more of the apparatuses and systems described herein. For example, the timing chart may represent the operation of a target memory device and a non-target memory device (e.g., either of which may be implemented by the memory devices 100, 212, 216, 232, and/or 236 of FIG. 2, and/or 300 of FIG. 3). FIG. 4 shows an embodiment where a burst length of 16 bits is used.

The timing chart 400 shows operation in a target memory device that the controller is performing a write operation on, and operation in a non-target memory device in a same memory module. The target memory device may be a first rank (here labelled Rank 0) and a second rank (here labelled Rank 1) of a memory module, such as the channels 210 and 230 of FIG. 2. The two ranks may share DQ terminals with each other.

The timing chart 400 shows a complementary clock signal CK_t and CK_c, chip select and command bus (e.g., CA bus) signals for the two ranks, the information along the DQ bus, and representations of the termination values of the two ranks.

At an initial time t0, the controller issues a write command to the target memory by sending a chip select signal CS to rank 1 and sending write commands along the CA bus to the target rank. At t0, the controller also sends a CS signal to the non-target rank 1, and sends NT-ODT adjustment signals along the CA bus to that rank. For example, signal may be sent along the designated pin (e.g., Command 0 of FIG. 3). At the initial time, since neither rank were targeted, the termination circuits in both ranks may default to an NT-ODT_R or NT-ODT read value.

At a first time t1, responsive to the write command and the NT-ODT adjustment command, the two ranks may begin to transition their respective termination impedance values. At the time t2, the termination circuits of rank 0 reaches a target ODT value, which is based on Rank 0 being the target rank. Meanwhile the termination circuits of rank 1 reaches a value NT-ODT_W, or a NT-ODT write value. The values NT-ODT_R, NT-ODT_W, and target ODT may be settings of the memories, and may be based on a training process. They may be the same or different from each other. The times t1 and t2 may be separated by a ODT activation time tODTon. At a time t3, the data terminals of the target rank may begin receiving data. In the example of FIG. 4, 16 serial bits are received as part of a burst length. The time from the end of the write command (and NT-ODT adjustment command) being received to the time t1 may be an ODT activation delay period ODTLon. The time between the write command being received (after t0) and the burst length beginning is write delay time WL.

At a time t4 which is after the burst length has ended, the ODT values in both ranks may begin transitioning again. Over an ODT deactivation period tODToff, the ranks each transition. After the time tODToff, at a time t5, both ranks have returned to the default value (NT-ODT_R). The time between the write and NT-ODT adjustment command being received and the second transition period (e.g., the end of the ODT values being adjusted) may be an ODT deactivation delay time ODTLoff. The difference between the times ODTLoff and ODTLon plus tODTon may represent the length of time that the ODT values are adjusted for responsive to the write command and NT-ODT adjustment command.

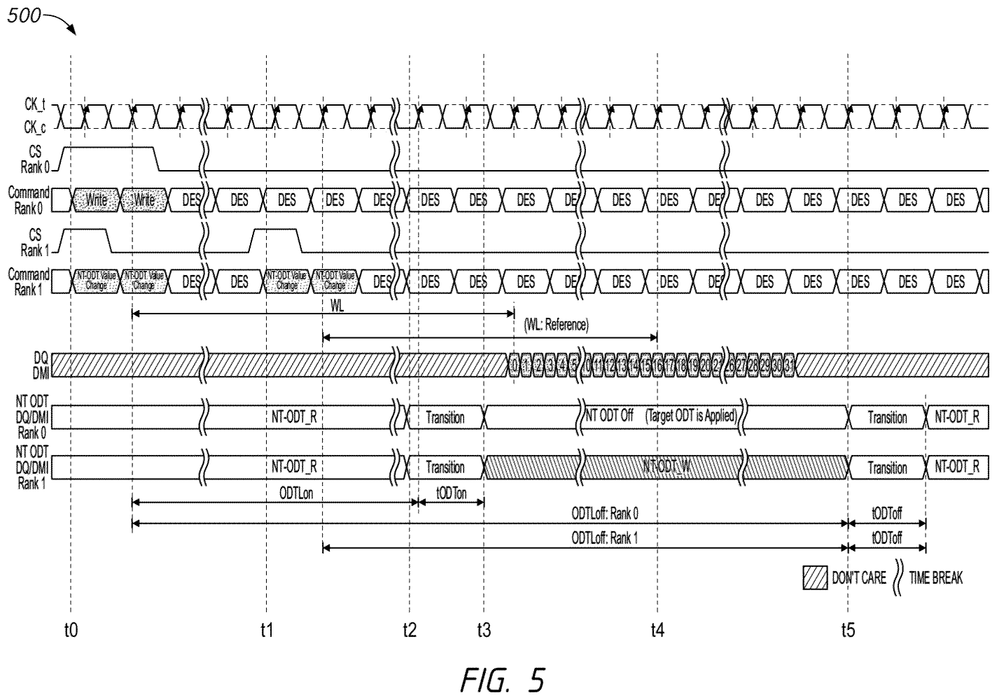

FIG. 5 is a timing chart of an NT-ODT adjustment according to some embodiments of the present disclosure. The timing chart 500 may, in some embodiments, represent the operation of one or more of the apparatuses and systems described herein. For example, the timing chart may represent the operation of a target memory device and a non-target memory device (e.g., either of which may be implemented by the memory devices 100, 212, 216, 232, and/or 236 of FIG. 2, and/or 300 of FIG. 3). The timing chart 500 of FIG. 5 represents an embodiment where a burst length of 32 is used. Since the timing chart 500 may generally be similar to the timing chart 400 of FIG. 4, details already explained with respect to the timing chart 400 will not be repeated again with respect to FIG. 5.

Similar to the timing chart 400, in the timing chart 500 at an initial time to, the controller issues a write command to rank 0 and an NT-ODT adjustment command to rank 1. However, since this is an embodiment with a burst length of 32, at a time t1, the controller issues a second NT-ODT adjustment command to Rank1. Accordingly, at t2 the two ranks begin transitioning (responsive to the write command and the first NT-ODT adjustment command) and at t3 the two ODT circuits reach their adjusted values (target ODT and NT-ODT_W respectively). At a time t4, the a burst length of 16 is reached, however a second period of NT-ODT adjustment may begin responsive to the second NT-ODT adjustment command received at the time t1 At the time t5, after the end of a 32 bit burst length, the two ranks may begin transitioning back to their default values (NT-ODT_R).

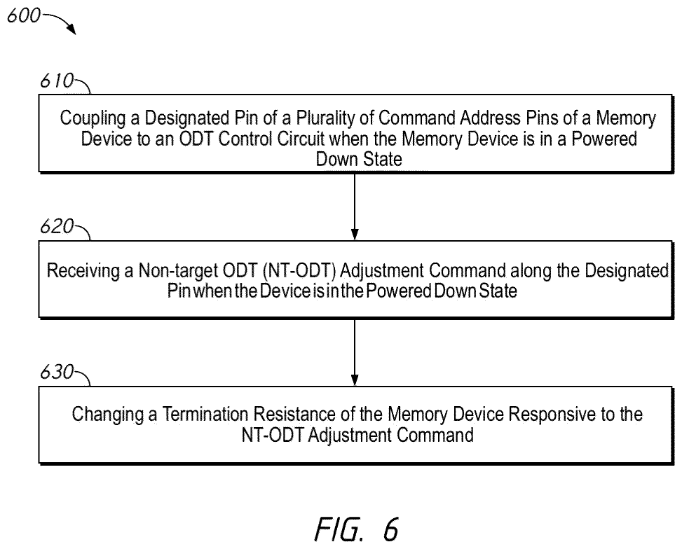

FIG. 6 is a flow chart of a method of non-target on-die termination adjustment in a powered down state according to some embodiments of the present disclosure. The method 600 may, in some embodiments, be performed by any of the apparatuses or systems described herein, such as the memory device 100 and/or 300 of FIGS. 1 and 3 and/or the memory module 202 of FIG. 2.

The method 600 may generally begin with box 610, which describes coupling a designated pin of a plurality of command address pins of a memory device to an ODT control circuit when the memory device is in a powered down state. For example, one of the CA pins (e.g., Command 0 of FIG. 3) may be coupled to an NT-ODT power down logic circuit (e.g., 152 of FIG. 1, 213 of FIG. 2, and/or 316 of FIG. 3) which bypasses the command decoder when the memory device is in a power down mode. When the device is in the power on mode, the method 600 may include coupling the designated pin to the command decoder. The method 600 may include receiving an NT-ODT adjustment command along multiple of the plurality of command address pins when the memory device is in the powered up state.

Box 610 may generally be followed by box 620, which describes receiving a NT-ODT adjustment command along the designated pin when the device is in the powered down state. For example, the NT-ODT adjustment command may be received from a controller while the controller is performing an access operation on another memory device which is part of a different memory rank of a module (e.g., 202 of FIG. 2).

Box 620 may generally be followed by box 630, which describes changing a termination resistance of the memory device responsive to the NT-ODT adjustment command. The method 600 may include changing the termination resistance for a set amount of time corresponding to a first burst length. The method 600 may include receiving two NT-ODT adjustment commands and changing the termination resistance for a different set amount of time corresponding to a second burst length (e.g., as shown in FIG. 5). The method 600 may include changing the termination resistance from an NT-ODT read value to an NT-ODT write value. The method 600 may include changing the termination resistance while the device remains in the powered down mode.

As used herein, an activation of a signal may refer to any portion of a signals waveform that a circuit responds to. For example, if a circuit responds to a rising edge, then a signal switching from a low level to a high level may be an activation. One example type of activation is a pulse, where a signal switches from a low level to a high level for a period of time, and then back to the low level. This may trigger circuits which respond to rising edges, falling edges, and/or signals being at a high logical level. One of skill in the art should understand that although embodiments may be described with respect to a particular type of activation used by a particular circuit (e.g., active high), other embodiments may use other types of activation (e.g., active low).

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of command address pins including a designated pin;
an on-die termination (ODT) control circuit; and
a termination circuit, wherein the ODT control circuit is configured to change a resistance of the termination circuit responsive to a signal received along the designated pin while the apparatus is in a powered down state.

2. The apparatus of claim 1, further comprising:
a command decoder; and
a non-target ODT (NT-ODT) power down logic circuit configured to couple the designated pin to the ODT control circuit when the apparatus is in the powered down state and configured to couple the designated pin to the command decoder when the apparatus is in the powered on state.

3. The apparatus of claim 2, wherein the command decoder is configured to receive an NT-ODT command along multiple of the plurality of command address pins when the apparatus is in the powered on state, and
wherein responsive to the NT-ODT command received by the command decoder, the ODT control circuit is configured to change the resistance of the termination circuit.

4. The apparatus of claim 1, wherein the signal is a binary signal, and wherein responsive to the signal the ODT control circuit is configured to change the resistance of the termination circuit from a first value to a second value.

5. The apparatus of claim 4, wherein the first value is a NT-ODT read value and second value is a NT-ODT write value.

6. The apparatus of claim 4, wherein responsive to the signal, the ODT control circuit is configured to change the resistance of the termination circuit for a set period of time.

7. The apparatus of claim command decoder configured to receive a signal along multiple of the CA pins in the powered on state.

8. A system comprising:
a first memory device comprising a first termination circuit;
a second memory device comprising a second termination circuit; and
a controller configured to perform an write operation on the first memory device and provide a non-target on-die termination (NT-ODT) adjustment command to the second memory device,
wherein the second memory device is configured to change a resistance of the second termination circuit responsive to the NT-ODT adjustment command while the second memory device is in a powered down state.

9. The system of claim 8, wherein the second memory device comprises:
a command decoder;
an on-die termination (ODT) control circuit;
an NT-ODT power down logic circuit configured to couple a designated pin of a plurality of command address pins to the on-die termination (ODT) control circuit when the device is in the powered down state, wherein the ODT control circuit is configured to change the resistance of the second termination circuit responsive to the command along the designated pin.

10. The system of claim 9, wherein the controller is configured to provide the NT-ODT adjustment command to the second memory device along the designated pin when the second memory device is in the powered downs state or along multiple of the command address pins when the second memory device is in a powered on state.

11. The system of claim 8, wherein the first termination circuit configured to change from a respective NT-ODT read value to a target ODT value responsive to the write operation, and
wherein the second termination circuit configured to change from a respective NT-ODT read value to a NT-ODT write value responsive to the NT-ODT adjustment command.

12. The system of claim 8, wherein the controller is configured to provide data for a burst length to the first memory device as part of the write operation, wherein the controller is further configured to provide one NT-ODT adjustment command for the burst length having a first value and two NT-ODT adjustment commands for the burst length having a second value.

13. The system of claim 8, wherein the controller configured to perform a second write operation on the second memory device and provide a second NT-ODT adjustment command to the first memory device, wherein the first memory device is configured to change a resistance of the first termination circuit responsive to the second NT-ODT adjustment command while the first memory device is in the powered down state.

14. The system of claim 8, wherein the first memory device and second memory device are in different ranks of a memory module.

15. A method comprising:
coupling a designated pin of a plurality of a plurality of command address pins of a memory device to an on-die termination (ODT) control circuit when the memory device is in a powered down state;
receiving a non-target ODT (NT-ODT) adjustment command along the designated pin when the memory device is in the powered down state; and
changing a termination resistance of the memory device responsive to the NT-ODT adjustment command.

16. The method of claim 15, further comprising changing the termination resistance for a set amount of time corresponding to a first burst length.

17. The method of claim 16, further comprising:
receiving two NT-ODT adjustment commands and changing the termination resistance for a different set amount of time corresponding to a second burst length.

18. The method of claim 15, further comprising coupling the designated pin to a command decoder of the memory device when the memory device is in a powered up state.

19. The method of claim 18, further comprising receiving the NT-ODT adjustment command along multiple of the plurality of command address pins when the memory device is in the powered up state.

20. The method of claim 15, further comprising changing the termination resistance from an NT-ODT read value to an NT-ODT write value.
